(19) United States
(12) Patent Application Publication
(10) Pub. No.: US 2013/0109289 A1
(43) Pub. Date: May 2, 2013

(54) ELECTRONIC DEVICE

(71) Applicants: WEI-CHENG CHENG, Tu-Cheng (TW); LEE-HUI KUO, Tu-Cheng (TW); CHIH-HANG CHAO, Tu-Cheng (TW); PO-YEN HSU, Tu-Cheng (TW); YEN-CHI TSAI, Tu-Cheng (TW); HUNG-CHING CHEN, Tu-Cheng (TW)

(72) Inventors: WEI-CHENG CHENG, Tu-Cheng (TW); LEE-HUI KUO, Tu-Cheng (TW); CHIH-HANG CHAO, Tu-Cheng (TW); PO-YEN HSU, Tu-Cheng (TW); YEN-CHI TSAI, Tu-Cheng (TW); HUNG-CHING CHEN, Tu-Cheng (TW)

(73) Assignee: HON HAI PRECISION INDUSTRY CO., LTD., Tu-Cheng (TW)

(21) Appl. No.: 13/535,284

(22) Filed: Jun. 27, 2012

(30) Foreign Application Priority Data
Oct. 31, 2011 (TW) 100139559

(51) Int. Cl. H05K 5/00

(52) U.S. Cl. 454/184

(57) ABSTRACT

An electronic device includes a housing, a covering module, and a temperature sensing module. The housing defines a cooling opening. The temperature sensing module is connected to the covering module and adapted to detect a temperature of the housing and output a control signal to the covering module. When the temperature of the housing is lower than a pre-set temperature, the covering module closes the cooling opening. When the temperature of the housing is equal or greater than the pre-set temperature, the control signal controls the covering module to move relative to the housing and open the cooling opening.

### BACKGROUND

1. Technical Field

The present disclosure relates to electronic devices, and particularly to an electronic device with a covering plate.

2. Description of Related Art

Electronic devices, such as computers, include a number of heat generating components, such as a CPU. The components generate different heat flux when they work under different states. Temperatures of the electronic devices may continue to rise as a working time of the number of heat generating components increases. Generally, users increase a rotation speed of a cooling fan to cool the electronic devices. However, increases of the rotation speed increasing may be noisy and consume more energy. Therefore, an improved electronic device may be desired.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block view of an electronic device in accordance with an embodiment.

FIG. 2 is an exploded, isometric view of a housing and a covering module of the electronic device of FIG. 1.

FIG. 3 is an exploded, isometric view of the covering module of FIG. 2.

FIG. 4 is similar to FIG. 3, but viewed from a different aspect.

FIG. 5 is an assembled, isometric view of the covering module of FIG. 3.

FIG. 6 is an assembled, isometric view of the housing and the covering module of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

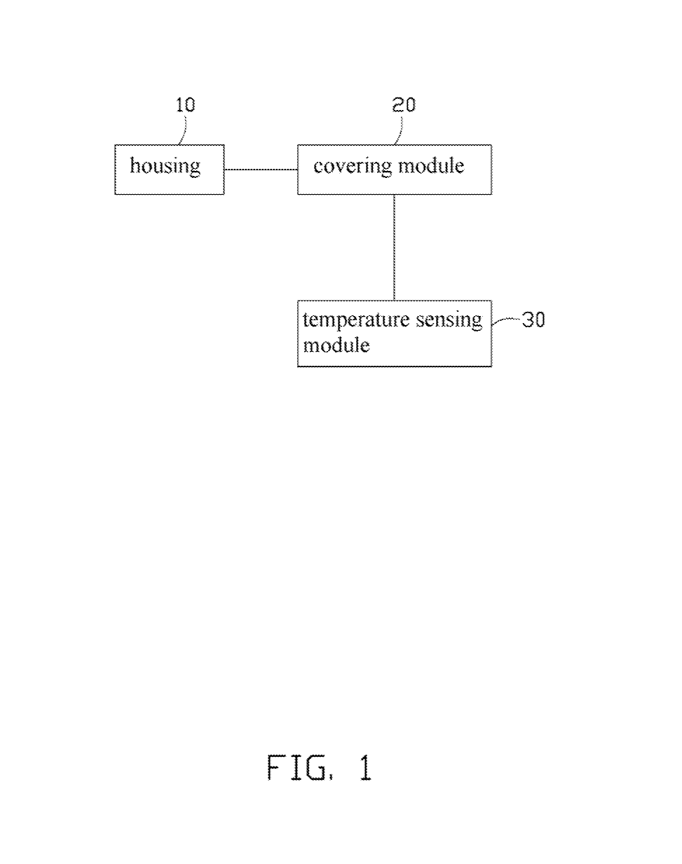

FIG. 1 shows an electronic device in accordance with an embodiment. The electronic device includes a housing 10, a covering module 20, and a temperature sensing module 30.

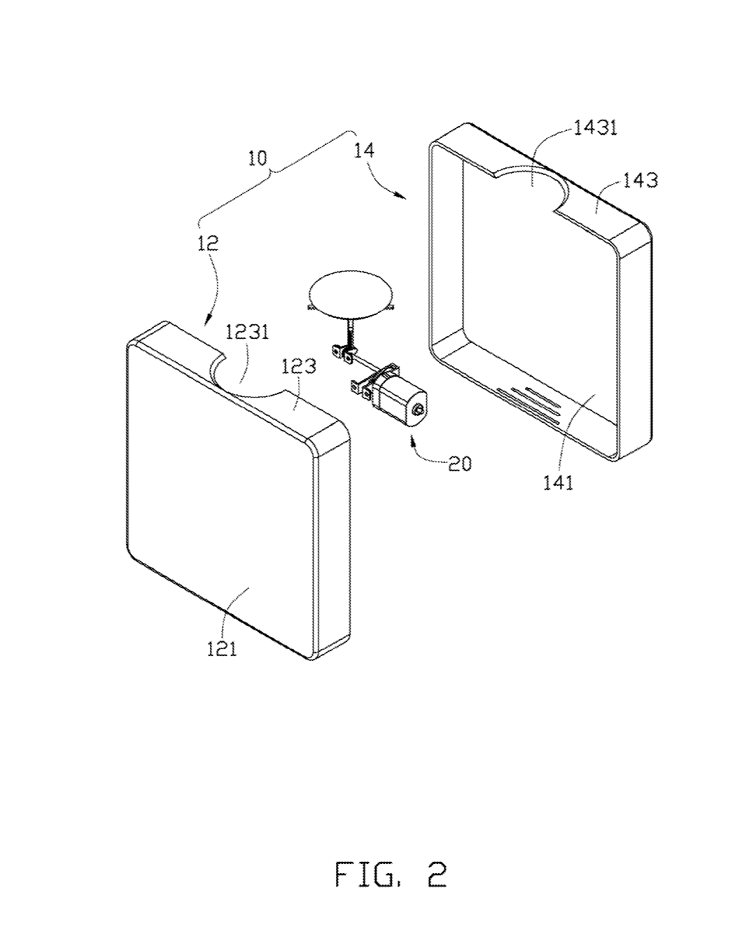

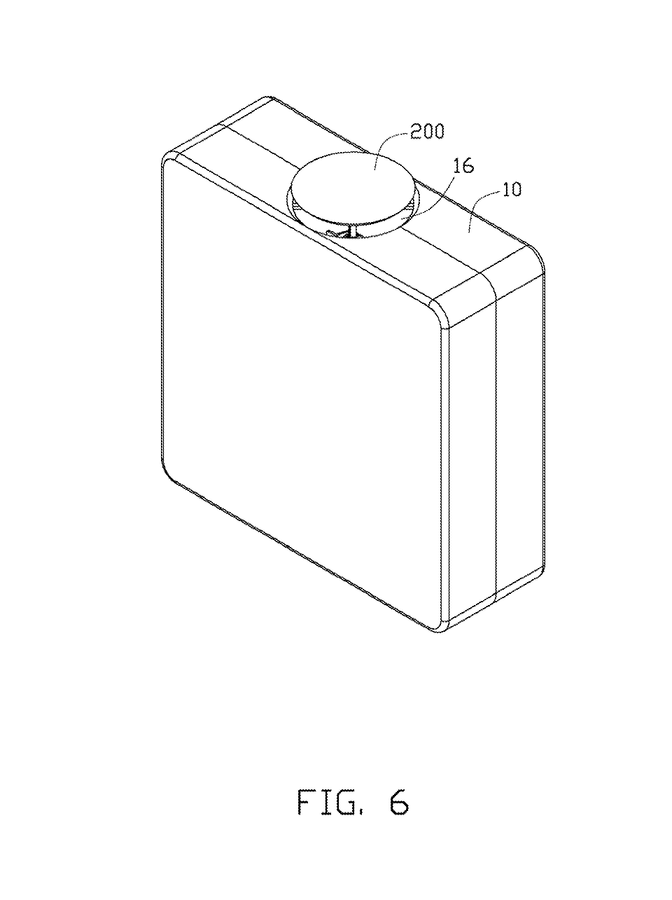

FIG. 2 shows the housing 10 including a first shell 12 and a second shell 14. The first shell 12 includes a first square plate 121 and four first flanges 123 extending from four edges of the first square plate 121. One of the four first flanges 123, extending from a top edge of the first square plate 121, defines a first cutout 1231. The second shell 14 includes a second square plate 141 and four second flanges 143 extending from four edges of the second square plate 141. One of the four second flanges 143, extending from a top edge of the second square plate 141, defines a second cutout 1431. In one embodiment, first shell 12 is similar with the second shell 14, and the first cutout 1231 and the second cutout 1431 are semicircle with a same size. When the first shell 12 is secured to the second shell 14, the first cutout 1231 and the second cutout 1431 may form a circular cooling opening 16 (shown as in FIG. 6).

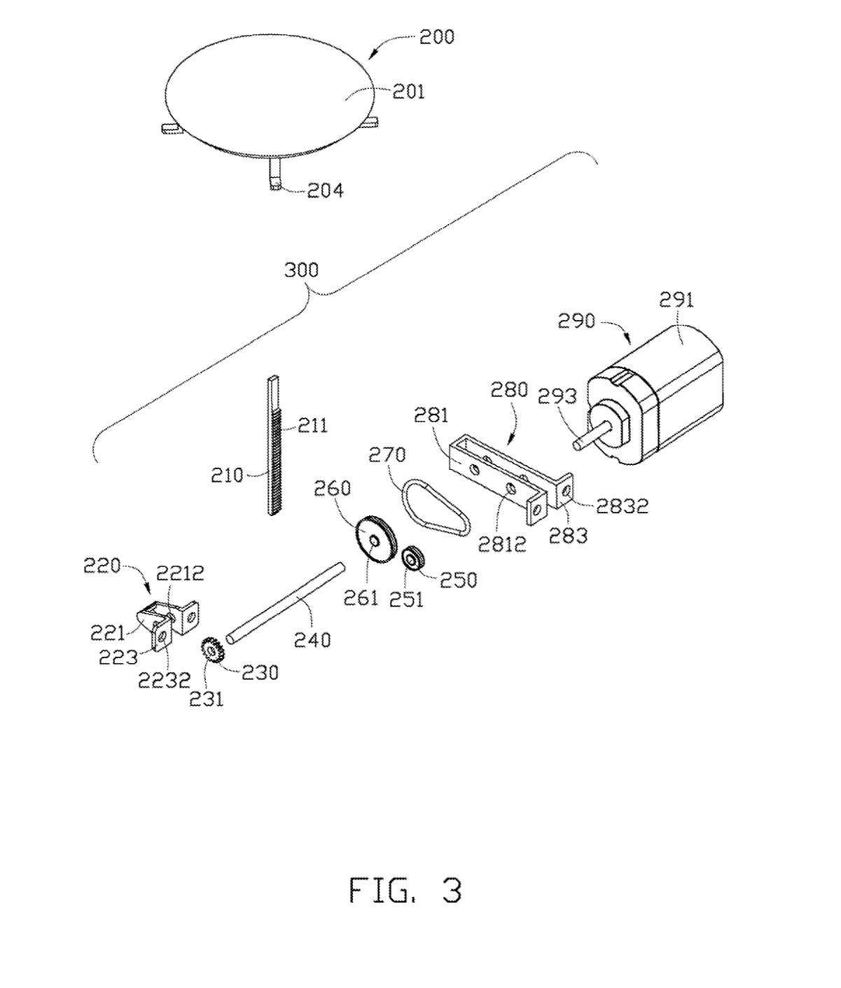

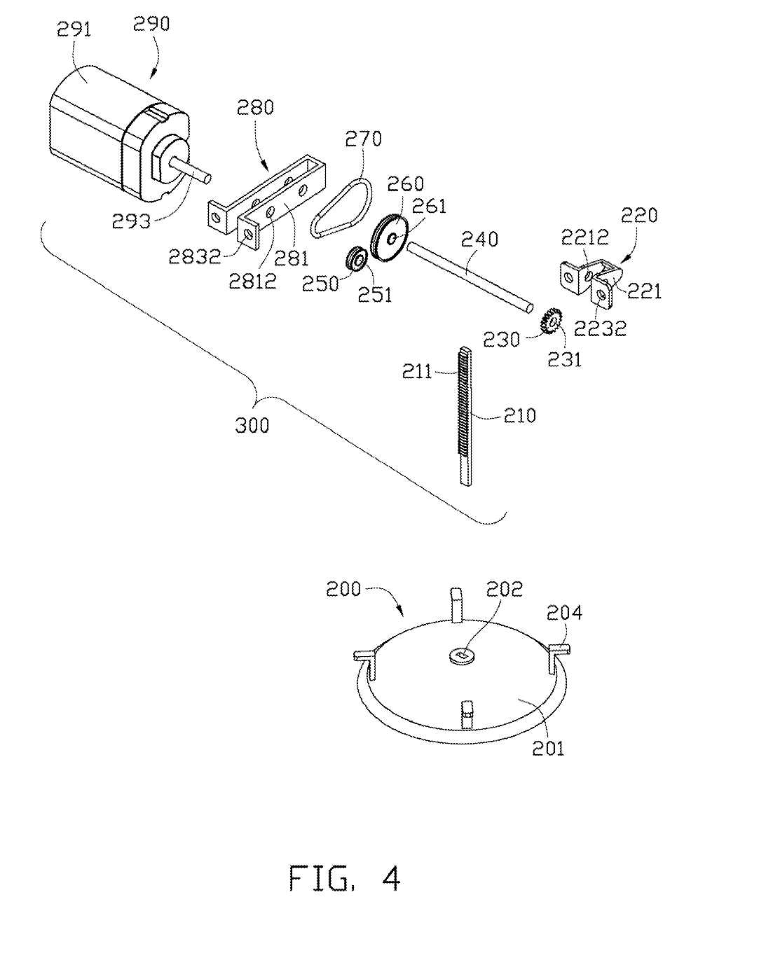

FIG. 3 and FIG. 4 show the covering module 20 of one embodiment. The covering module 20 includes a covering plate 200 and a pushing assembly 300. The pushing assembly 300 includes a rack 210, a first installation member 220, a gear member 230, a pivoting shaft 240, a first turntable 250, a second turntable 260, a belt 270, a second installation member 280, and a motor 290.

The covering plate 200 includes a plate body 201 and a plurality of limiting portions 204 located on the plate body 201. In one embodiment, the plate body 201 is circular, and each of the plurality of the limiting portions 204 has an “L” shaped. A size of the plate body 201 is substantially equal to a size of the cooling opening 16. The plate body 201 defines an installation slot 202 in a central portion of the plate body 201. The plurality of limiting portions 204 are arranged in a circle of the plate body 201 of equidistance.

The rack 210 is a strip. A plurality of teeth 211 are located on a side surface of the rack 210.

The first installation member 220 includes two first side plates 221. Each of the two first side plates 221 defines a first pivoting hole 2212. A first locking piece 223 extends from each of the two first side plates 221. The first locking piece 223 defines a first locking hole 2232. In one embodiment, the first locking piece 223 is substantially perpendicular to the two first side plates 221.

The gear member 230 defines an installation hole 231. The gear member 230 may be geared with the teeth 211 of the rack 210.

The first turntable 250 defines a first mounting hole 251. The second turntable 260 defines a second mounting hole 261. In one embodiment, the first turntable 250 and the second turntable 260 are circular. A diameter of the first turntable 250 is greater than a diameter of the second turntable 260. The belt 270 may surround the first turntable 250 and the second turntable 260 and rotate together with the first turntable 250 and the second turntable 260.

The second installation member 280 includes two second side plates 281. Each of the two second side plates 281 defines two second pivoting holes 2812. A second locking piece 283 extends from each of the two second side plates 281. The second locking piece 283 defines a second locking hole 2832. In one embodiment, the second locking piece 283 is substantially perpendicular to the two second side plates 281.

The motor 290 includes a motor body 291 and a rotating shaft 293 attached to the motor body 291. The rotating shaft 293 is rotatable along a clockwise direction or an anticlockwise direction when the motor 290 is powered on. A cross-section of the rotating shaft 293 is substantially equal to a cross-section of the pivoting shaft 240.

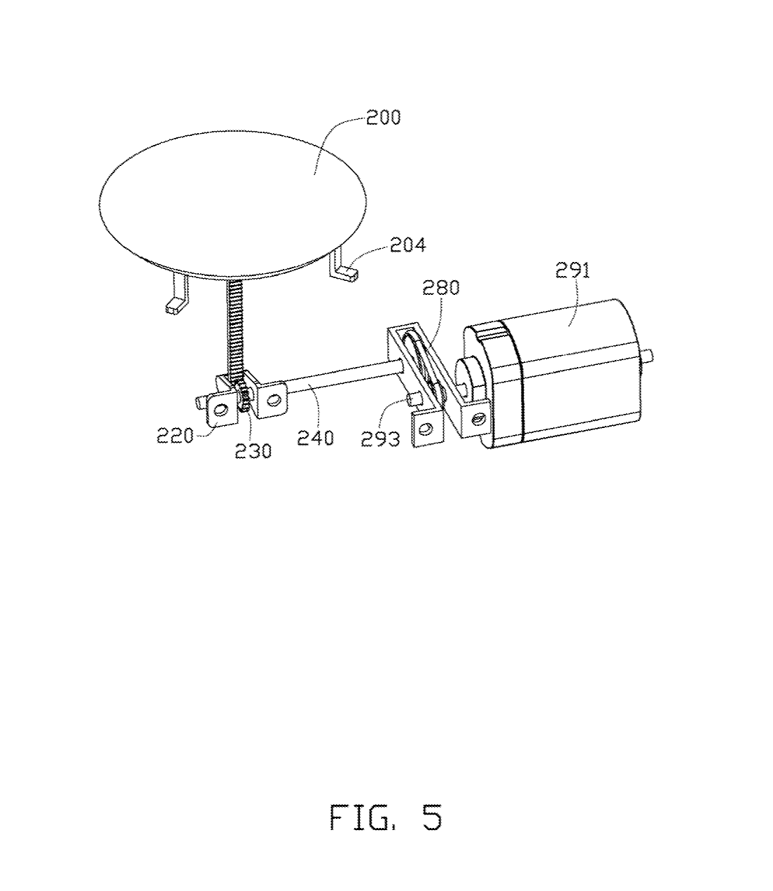

FIG. 5 and FIG. 6 show that, in assembly, the first turntable 250 and the second turntable 260 are located between the two second side plates 281, and each of the first mounting hole 251 and the second mounting hole 261 is aligned with each of the two second pivoting holes 2812. The rotating shaft 293 is engaged in the second pivoting hole 2812 and the first mounting hole 251, thereby the rotating shaft 293 can cause the first turntable 250 to rotate. A first end of the pivoting shaft 240 is engaged in the second mounting hole 261 and the second pivoting hole 2812, to secure the pivoting shaft 240 to the second turntable 260. The belt 270 surrounds the first turntable 250 and the second turntable 260. The gear member 230 is located between the two first side plates 221, and the installation hole 231 is aligned with the first pivoting hole 2212. A second end of the pivoting shaft 240 is engaged in the installation hole 231, to secure gear member 230 to the pivoting shaft 240. The second end of the pivoting shaft 240 is opposite to the first end of the pivoting shaft 240.

A first locking member (not shown), such as a screw, is inserted into the first locking hole 2232 and the first shell 12 or the second shell 14, to secure the first installation member 220 to the first shell 12 or the second shell 14. A second locking member (not shown), such as a screw, is inserted into the second locking hole 2832 and the first shell 12 or the second shell 14, to secure the second installation member 280 to the first shell 12 or the second shell 14. A first end of the rack 210 is engaged in the installation slot 202. A second of the rack 210, opposite to the first end, is located between the two first side plates 221 and geared with the gear member 230. The first shell 12 is secured to the second shell 14, and the first cutout 121 and the second cutout 141 together form a circular cooling opening 16. The covering plate 200 is located in the cooling opening 16 and covers the cooling opening 16. In this position, the covering plate 200 is located in an initial position. The temperature sensing module 30 is connected to the covering module 20. The temperature sensing module 30 may detect a temperature of the housing 10 and transmit a control signal to the covering module 20.

In use, the temperature sensing module 30 may detect a temperature of the housing 10 and output a control signal to the covering module 20. When the temperature is lower than a pre-set temperature, the motor 290 of the covering module 20 does not work, and the covering plate 200 is in the initial position. In this position, the housing 10 is closed and beautiful. When the temperature is equal or greater than the pre-set temperature, the control signal controls the motor 290 to start to operate, the rotating shaft 293 is rotated along the clockwise direction and rotates the first turntable 250 and the second turntable 260 to rotate along the clockwise direction. The second turntable 260 rotates the pivoting shaft 240 and the gear member 230 to rotate along the clockwise direction. The gear member 230 urges the rack 210 to move upwards. The covering plate 200 is moved upwards together with the rack 210 and located above the cooling opening 16. In this position, the covering plate 200 is located in an open position, the cooling opening 16 opens and heated air can flow out of the housing 10 from the cooling opening. The pivoting shaft 240 and the rotating shaft 293 are substantially perpendicular to a sliding direction of the covering plate and the rack 210, and the pivoting shaft 240 is substantially parallel to the rotating shaft 293. The limiting portion 204 can be engaged with an inner surface of the housing 10 when the covering plate 200 is moved upwards, to restrict the covering plate 200 from moving to a limited height. When the temperature falls lower than the pre-set temperature, the motor 290 is rotated anticlockwise to rotate the gear member 230 anticlockwise. The gear member 230 urges the rack 210 to move downwards to pull the covering plate 200 to cover the cooling opening 16. In this position, the cooling opening 16 is closed, and the covering plate is located in the initial position.

In other embodiments, the covering plate 200 can be automatically pushed by another pushing assembly, different from the pushing assembly 300, according to the temperature of the housing 10. The pushing assembly 300 includes the motor 290, the first turntable 250, the second turntable 260, the belt 270, the first installation member 220, the second installation member 280, the gear member 230, the pivoting shaft 240, and the rack 210.

It is to be understood, however, that even though numerous characteristics and advantages have been set forth in the foregoing description of embodiments, together with details of the structures and functions of the embodiments, the disclosure is illustrative only and changes ay be made in detail, especially in the matters of shape, size, and arrangement of parts within the principles of the disclosure, to the full extent indicated by the broad general meaning of the terms in which the appended claims are expressed.

What is claimed is:

1. An electronic device comprising:
a housing defining a cooling opening;
a covering module; and
a temperature sensing module connected to the covering module and adapted to detect a temperature of the housing and to control the covering module by outputting a control signal to the covering module;
wherein when the temperature of the housing is lower than a pre-set temperature, the covering module closes the cooling opening; when the temperature of the housing is equal or greater than the pre-set temperature, the temperature sensing module outputs the control signal to move the covering module relative to the housing and to open the cooling opening.

2. The electronic device of claim 1, wherein the covering module comprises a covering plate and a pushing assembly secured to the covering plate; when the temperature is lower than the pre-set temperature, the covering plate is located in the cooling opening and covers the cooling opening; when the temperature is equal of higher than the pre-set temperature, the pushing assembly pushes the covering plate to move out of the cooling opening and opens the cooling opening.

3. The electronic device of claim 2, wherein the pushing assembly comprises a rack secured to the covering plate, a gear member geared with the rack, and a motor connected to the gear member; the motor is rotatable to rotate the gear member, and the gear member is rotatable to slide the rack and the covering plate.

4. The electronic device of claim 3, wherein the pushing assembly further comprises a pivoting shaft, a first turntable, a second turntable, and a belt surrounding the first turntable and the second turntable; a first end of the pivoting shaft is secured to the gear member, a second end of the pivoting shaft is secured to the second turntable, and the first end of the pivoting shaft is opposite to the second of the pivoting shaft; the motor comprises a rotating shaft secured to the first turntable, and the rotating shaft is rotatable to rotate the pivoting shaft together with the gear member through the first turntable, the belt, and the second turntable.

5. The electronic device of claim 4, wherein the rack is slidable along a first direction, and the pivoting shaft is substantially perpendicular to the first direction.

6. The electronic device of claim 5, wherein the pivoting shaft is substantially parallel to the rotating shaft, and the rotating shaft is substantially perpendicular to the first direction.

7. The electronic device of claim 4, wherein the pushing assembly further comprises a second installation member, the second installation member comprises two second side plates and two second locking pieces, and each of the two second locking pieces extends from each of the two second side plates and is secured to the housing; and the first turntable and the second turntable are located between the two second side plates.

8. The electronic device of claim 3, wherein the pushing assembly further comprises a first installation member, the first installation member comprises two first side plates and two first locking pieces, and each of the two first locking pieces extends from each of the two first side plates and is secured to the housing; and the gear member and the rack are located between the two first side plates.

9. The electronic device of claim 2, wherein the covering plate further comprises at least one limiting portion secured to a bottom surface of the covering plate, and the at least one limiting portion is engaged with the housing when the covering plate is slid relative to the housing to open the cooling opening, and to restrict the covering plate from moving to a limited height.

10. The electronic device of claim 9, wherein the at least one limiting portion has an “L” shape.

11. An electronic device comprising:
a housing defining a cooling opening;
a covering module comprising a covering plate and a pushing assembly secured to the covering plate; and
a temperature sensing module connected to the pushing module and adapted to detect a temperature of the housing and to control the pushing module by outputting control signals to the pushing module;
wherein when the temperature of the housing is lower than a pre-set temperature, the covering plate is located in the cooling opening and closes the cooling opening; when the temperature of the housing is equal or greater than the pre-set temperature, temperature sensing module outputs the control signals to the pushing module to slide the covering plate out of the cooling opening, thereby opening the cooling opening.

12. The electronic device of claim 11, wherein the pushing assembly comprises a rack secured to the covering plate, a gear member geared with the rack, and a motor connected to the gear member; the motor is rotatable to rotate the gear member, and the gear member is rotatable to slide the rack and the covering plate.

13. The electronic device of claim 12, wherein the pushing assembly further comprises a pivoting shaft, a first turntable, a second turntable, and a belt surrounding the first turntable and the second turntable; a first end of the pivoting shaft is secured to the gear member, a second end of the pivoting shaft is secured to the second turntable, and the first end of the pivoting shaft is opposite to the second of the pivoting shaft; the motor comprises a rotating shaft secured to the first turntable, and the rotating shaft is rotatable to rotate the pivoting shaft together with the gear member through the first turntable, the belt, and the second turntable.

14. The electronic device of claim 13, wherein the rack is slidable along a first direction, and the pivoting shaft is substantially perpendicular to the first direction.

15. The electronic device of claim 14, wherein the pivoting shaft is substantially parallel to the rotating shaft, and the rotating shaft is substantially perpendicular to the first direction.

16. The electronic device of claim 13, wherein the pushing assembly further comprises a second installation member, the second installation member comprises two second side plates and two second locking pieces, and each of the two second locking pieces extends from each of the two second side plates and is secured to the housing; and the first turntable and the second turntable are located between the two second side plates.

17. The electronic device of claim 13, wherein each of the first turntable and the second turntable is circular, and a diameter of the first turntable is smaller than a diameter of the second turntable.

18. The electronic device of claim 12, wherein the pushing assembly further comprises a first installation member, the first installation member comprises two first side plates and two first locking pieces, and each of the two first locking pieces extends from each of the two first side plates and is secured to the housing; and the gear member and the rack are located between the two first side plates.

19. The electronic device of claim 11, wherein the covering plate further comprises at least one limiting portion secured to a bottom surface of the covering plate, and the at least one limiting portion is engaged with the housing when the covering plate is slid relative to the housing, and to restrict the covering plate from moving to a limited height.

20. The electronic device of claim 19, wherein the at least one limiting portion has an “L” shape.
